(19) United States
(12) Patent Application Publication
(10) Pub. No.: US 2026/0086465 A1
(43) Pub. Date: Mar. 26, 2026

(54) SULFUR BASED RESIST HARDENING

(71) Applicant: Applied Materials, Inc., Santa Clara, CA (US)

(72) Inventors: RUDY WOJTECKI, East Garrison, CA (US); ZHIYU HUANG, Sunnyvale, CA (US)

(21) Appl. No.: 19/309,407

(22) Filed: Aug. 25, 2025

Related U.S. Application Data
(60) Provisional application No. 63/697,466, filed on Sep. 21, 2024.

(51) Int. Cl. G03F 7/40; G03F 7/039; G03F 7/09; H01L 21/311

(52) U.S. Cl. CPC G03F 7/40; G03F 7/0392; G03F 7/094; H10P 50/73

(57) ABSTRACT

Embodiments described herein relate to a method for transferring a pattern in a resist layer into a patterning stack under the resist layer. In an embodiment, the method includes treating the resist layer with a treatment that incorporates sulfur into a surface of the resist layer after the pattern is formed in the resist layer, and transferring the pattern in the resist layer into the patterning stack.

### CROSS-REFERENCE TO RELATED APPLICATIONS

This application claims the benefit of U.S. Provisional Application No. 63/697,466, filed on Sep. 21, 2024, the entire contents of which are hereby incorporated by reference herein.

### BACKGROUND

### 1) Field

Embodiments relate to the field of semiconductor manufacturing and, in particular, extreme ultraviolet (EUV) patterning of a resist layer with improved etch selectivity through the incorporation of sulfur into surfaces of the resist layer.

### 2) Description of Related Art

Extreme ultraviolet (EUV) photoresists allow for the continued scaling to smaller features that are patterned on a semiconductor substrate. In an EUV lithography process, EUV radiation is selectively applied to regions of the resist layer in order to generate a solubility switch that enables the formation of a desired pattern within the resist layer. In existing EUV resist materials, the sensitivity of the resist is low. That is, long EUV exposure durations are necessary in order to fully convert an exposed region into a soluble material capable of being removed with the developing process (e.g., a wet etching process). This can lead to low throughputs for EUV lithography processes.

Additionally, existing EUV photoresist materials may not have the desired etch selectivity to underlying layers, such as an underlying patterning stack. This may result in a need to increase the thickness of the EUV photoresist material in order to prevent the EUV photoresist layer from being completely removed during the pattern transfer process. However, increasing the thickness of the EUV photoresist layer may further increase the duration needed for the EUV exposure. Thicker EUV photoresist layers may also negatively impact different parameters of the etching process, such as line edge roughness (LER), resolution, and/or the like. This may be due, at least in part, to the limited depth of focus that is available for high numerical aperture (NA) EUV lithography exposure processes. Additionally, pattern collapse may result from thicker photoresist layers as the aspect ratio approaches 3:1 (height-width) or greater due to lines bending and touching each other.

### SUMMARY

Embodiments described herein relate to a method for transferring a pattern in a resist layer into a patterning stack under the resist layer. In an embodiment, the method includes treating the resist layer with a treatment that incorporates sulfur into a surface of the resist layer after the pattern is formed in the resist layer, and transferring the pattern in the resist layer into the patterning stack.

Embodiments described herein relate to a method for transferring a pattern formed into a positive tone chemically amplified resist (CAR) into a patterning stack below the underlayer. In an embodiment, the method includes treating the resist layer with a treatment that incorporates sulfur into a surface of the resist layer after the pattern is formed in the resist layer. In an embodiment, the surface with integrated sulfur has a higher etch resistivity than regions of the resist layer without the sulfur.

Embodiments described herein relate to a method that includes treating a patterned resist layer with a treatment, where the resist layer is provided over a patterning stack, and where the treatment incorporates sulfur into a top surface of the resist layer and a sidewall surface of the resist layer. In an embodiment, the method further includes transferring a pattern of the patterned resist layer into the patterning stack with an etching process.

### BRIEF DESCRIPTION OF THE DRAWINGS

FIG. 1A is a cross-sectional illustration of a device with a patterned resist layer over a patterning stack, in accordance with an embodiment.

FIG. 1B is a cross-sectional illustration of the device in FIG. 1A after the pattern of the resist layer is transferred into an underlying patterning stack and the resist layer is depleted in some areas before the etching process is completed, in accordance with an embodiment.

FIGS. 2A-2D are cross-sectional illustrations that depict a process for patterning a resist layer and applying a sulfurization treatment in order to improve the etch resistance of the resist layer, in accordance with an embodiment.

FIG. 3 is a cross-sectional illustration of a plasma-based sulfurization process of a patterned resist layer, in accordance with an embodiment.

FIGS. 4A-4C are cross-sectional illustrations that depict a three-operation plasma-free sulfurization process of a patterned resist layer, in accordance with an embodiment.

FIGS. 5A and 5B are cross-sectional illustrations that depict a two-operation plasma-free sulfurization process of a patterned resist layer, in accordance with an embodiment.

FIG. 6 is a flow diagram that depicts a process for sulfurizing a patterned resist layer, in accordance with an embodiment.

FIG. 7 is a flow diagram that depicts a plasma-based sulfurization process of a patterned resist layer, in accordance with an embodiment.

FIG. 8 is a flow diagram that depicts a three-operation plasma-free sulfurization process, in accordance with an embodiment.

FIG. 9 is a flow diagram that depicts a two-operation plasma-free sulfurization process, in accordance with an embodiment.

FIG. 10 illustrates a block diagram of an exemplary computer system that may be used in conjunction with a processing tool, in accordance with an embodiment.

### DETAILED DESCRIPTION

Embodiments described herein include extreme ultraviolet (EUV) patterning of a resist layer with improved etch selectivity through the incorporation of sulfur into surfaces of the resist layer. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, high numerical aperture (NA) extreme ultraviolet (EUV) lithography allows for the formation of small features in a device in order to enable further scaling of semiconductor devices. However, the poor sensitivity of existing EUV resist materials may require long duration EUV exposure processes. The exposure duration is further increased when the thickness of the EUV resist needs to be increased in order to account for the poor etch selectivity with underlying layers, such as an underlying patterning stack. Additionally, when a thickness of the EUV is increased, patterning outcomes may be suboptimal. For example, the limited depth of focus available in high NA EUV exposure tools may result in poor line edge roughness (LER) and/or poor resolution.

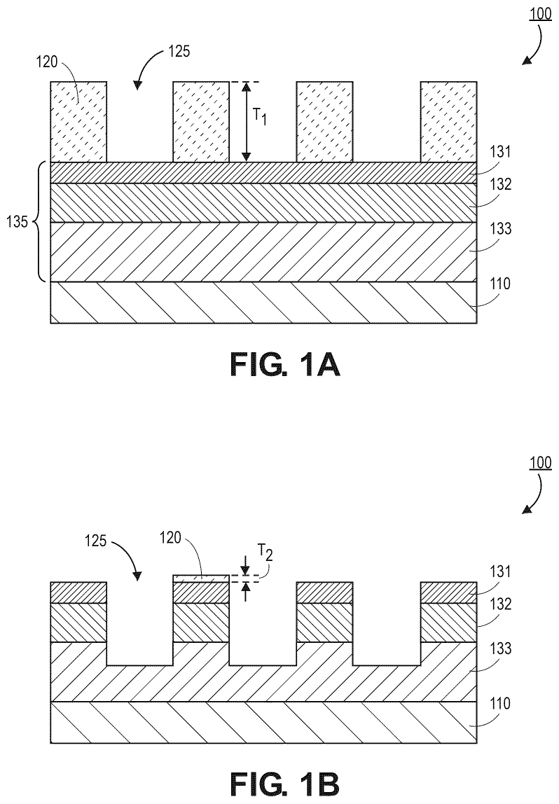

An example of such a limitation in existing EUV lithography processes is shown in FIGS. 1A and 1B. FIG. 1A is a cross-sectional illustration of a portion of a device 100. The device 100 may comprise a substrate 110 with an overlying patterning stack 135. The substrate 110 may be a semiconductor substrate, such as a silicon wafer or the like. The patterning stack 135 may comprise any number of layers used to provide an efficient transfer of a pattern into the underlying substrate 110. For example, the patterning stack 135 may comprise a carbon layer 133, a hardmask layer 132 (such as a silicon hardmask layer 132), and an underlayer 131. Though, additional layers, fewer layers, and/or layers with different functionalities may also be included in the patterning stack 135. A resist layer 120 may be provided over the patterning stack 135.

In some instances, the resist layer 120 may include a photoresist material that is compatible with EUV lithography processes. For example, the resist layer 120 may comprise a chemically amplified resist (CAR). In some embodiments, the resist layer 120 may also comprise an underlayer, such as a reflowable polymer underlayer. When exposed to EUV radiation, the resist layer 120 may undergo a chemical reaction (e.g., a deprotection reaction) in order to render the exposed regions soluble to a developer chemistry (e.g., a wet etching chemistry). As shown in FIG. 1A, the resist layer 120 may be patterned in order to form one or more openings 125 through a thickness of the resist layer 120. The openings 125 may be trenches, holes, or the like. The resist layer 120 in FIG. 1A may have a first thickness T₁.

Referring now to FIG. 1B, a cross-sectional illustration of the portion of the device 100 after the pattern of the openings 125 in the resist layer 120 is transferred into one or more layers of the patterning stack 135. Due to the poor etch selectivity between materials of the resist layer 120 and one or more layers of the patterning stack 135, the resist layer 120 is reduced in thickness. For example, a residual portion of the resist layer 120 may have a second thickness T₂ that is smaller than the first thickness T₁. In some instances, the resist layer 120 may be completely removed from some portions of the patterning stack 135 before the pattern of the openings 125 is completely transferred through the patterning stack 135. As such, continued etching may negatively impact the geometry of the pattern that is transferred into the patterning stack 135 and/or the substrate 110. Further, since a large first thickness T₁ is used to accommodate erosion of the resist layer 120 during the pattern transfer process, the depth of focus limitations of the EUV exposure may result in poor LER and/or poor resolution.

Accordingly, embodiments disclosed herein may include a process that increases the etch selectivity between the resist layer and the patterning stack. For example, surfaces of the resist layer may be sulfurized before the pattern is transferred into the patterning stack. The sulfurization process may result in the integration of sulfur into exposed surfaces of the resist layer. For example, a top surface and sidewall surfaces of the openings may be sulfurized in some embodiments.

In an embodiment, several different types of sulfurization processes may be used to treat the resist layer. In one embodiment, the sulfurization process may include a plasma-based sulfurization process. In such an embodiment, the plasma may be implemented without a bias in order to prevent degradation of the pattern fidelity, while also minimally etching the resist layer to maintain a desired resist layer thickness. For example, the plasma may include the use of a gas that comprises sulfur and fluorine (e.g., SF₆), carbon and sulfur (e.g., CS₂), carbon, oxygen, and sulfur (e.g., COS), or sulfur and oxygen (e.g., SO₂).

In other embodiments, plasma-free processes may be used in order to sulfurize the patterned resist layer. In one such embodiment, the patterned resist layer is exposed to a blanket ultraviolet (UV) exposure in order to convert ester resin into deprotected carboxylic acids. Thereafter, a neutralization chemistry (e.g., NF₃) may be exposed to the patterned resist layer in order to neutralize acid groups at the surface of the resist layer, which may produce carboxylate salts. Finally, the exposed and neutralized polymer resin of the resist layer is exposed to a sulfur containing chemistry (e.g., SO₂) in order to drive an uptake of sulfur into surfaces of the resist layer.

In another plasma free-process, the blanket UV exposure is used on the patterned resist layer. Thereafter, a sulfur-based chemistry (e.g., H₂S) is exposed to the surfaces of the patterned resist layer to form thioester bonds and incorporate sulfur into the surfaces of the patterned resist layer.

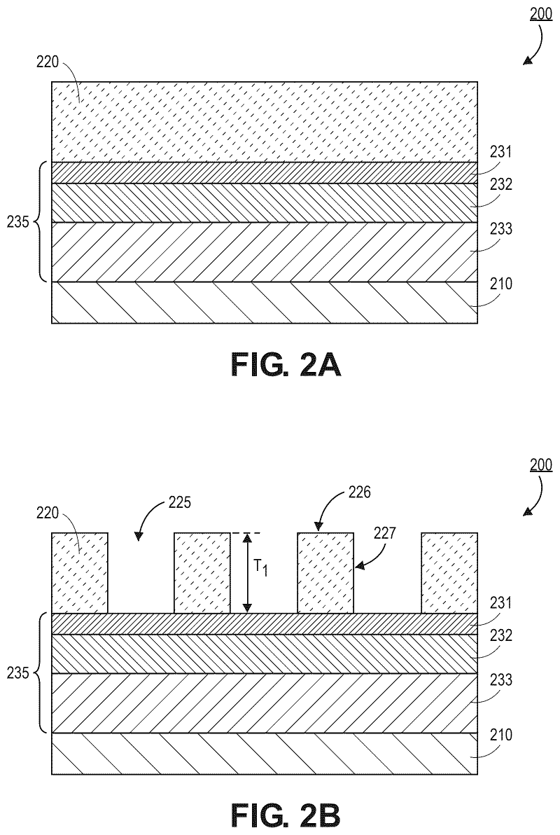

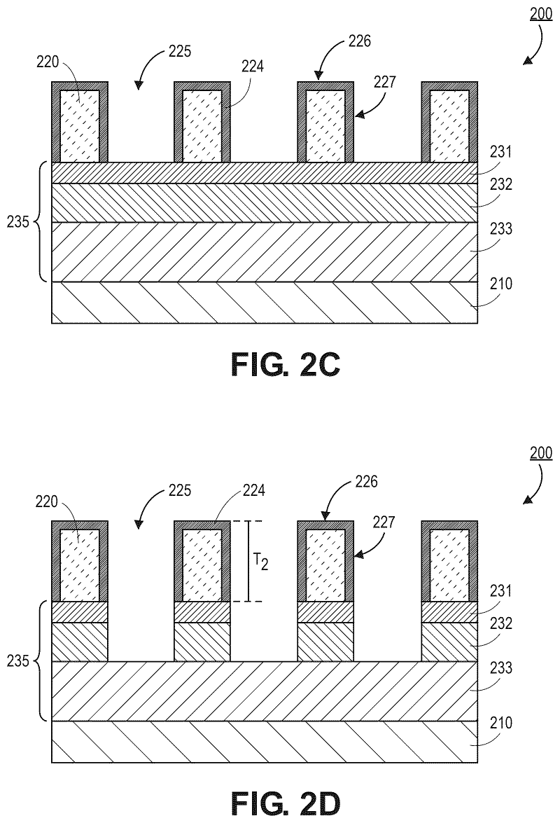

Referring now to FIGS. 2A-20, a series of cross-sectional illustrations of a device 200 that illustrate a process for transferring a pattern in a resist layer 220 into an underlying patterning stack 235 through the use of a sulfurized resist layer 220 is shown, in accordance with an embodiment.

Referring now to FIG. 2A, a cross-sectional illustration of a portion of the device 200 is shown, in accordance with an embodiment. As shown, the device 200 may comprise a substrate 210 and a patterning stack 235 may be provided over the substrate 210. In an embodiment, the substrate 210 may comprise any substrate used in semiconductor manufacturing. For example, the substrate 210 may comprise a semiconductor substrate, such as a silicon substate, a III-V semiconductor substrate, or the like. In an embodiment, the substrate 210 may also refer to a dielectric layer (e.g., silicon dioxide, silicon nitride, etc.), a metal layer, and/or the like that is provided over an underlying semiconductor layer.

In an embodiment, the patterning stack 235 may include any number of layers in order to implement a desired patterning result. For example, layers 231-233 are shown in FIG. 2A. The layers 231-233 may include materials that function as hardmask layers, antireflective coating layers, underlayers to improve the development process within the overlying photoresist layer, or the like. For example, the layer 231 may comprise an underlayer material that is used to augment the deprotection reaction in the overlying resist layer 220. For example, exposure of the layer 231 to EUV radiation may result in the diffusion of species into the resist layer 220 in order to drive the deprotection reaction within the resist layer 220 faster or more efficiently. In an embodiment, the layer 232 may be a hardmask material, such one that comprises silicon (e.g., amorphous silicon, SiON, or the like). In an embodiment, the layer 233 may comprise a carbon-based layer. While one particular patterning stack 235 is shown in FIG. 2A, it is to be appreciated that the patterning stack 235 may comprise one or more layers that are suitable for pattern transfer for a given patterning process. For example, an oxide layer may be provided between the layer 233 and the substrate 210 in some embodiments.

In an embodiment, a resist layer 220 is provided over the patterning stack 235. In an embodiment, the resist layer 220 may comprise any suitable photoresist material that is compatible with a given lithography process. For example, the photoresist material may be compatible with a deep ultraviolet (DUV) lithography process, an EUV lithography process, or the like. In a particular embodiment, the patterned resist layer 220 may comprise a CAR. In some embodiments, the resist layer 220 may also comprise an underlayer, such as a reflowable polymer underlayer. In some instances, the underlayer portion of the resist layer may also benefit from sulfurization processes described herein. The photoresist material may be a positive tone resist in some embodiments. The resist layer 220 may be formed over the patterning stack 235 with any suitable process. For example, the resist layer 220 may be formed with a dry deposition process (e.g., CVD, atomic layer deposition (ALD), or the like). Other embodiments may include forming the resist layer 220 with a wet process, such as a spin-coating process or the like.

Referring now to FIG. 2B, a cross-sectional illustration of the portion of the device 200 after the resist layer 220 is patterned is shown, in accordance with an embodiment. In an embodiment, the resist layer 220 may be patterned with an EUV exposure process or DUV exposure process. The exposure process may include exposing regions of the resist layer 220 with EUV radiation and/or DUV radiation in order to implement a solubility switch in the resist layer 220. In some embodiments, the exposure may be made through a mask, a reticle, a direct laser writing, or the like. In an embodiment, the exposed regions may undergo a chemical reaction in response to the exposure, such as a deprotection reaction or the like. In an embodiment, the chemical reaction may render the exposed regions etch selective to the unexposed regions of the resist layer 220. In some embodiments, a bake or annealing process may follow the exposure in order to further enhance the chemical reaction within the exposed regions.

In an embodiment, the resist layer 220 may be developed with a wet developing process (e.g., a wet etching chemistry) that selectively removes the exposed regions of the resist layer 220. The developing process may result in the formation of openings 225 through a thickness of the resist layer 220. For example, the resist layer 220 may have a first thickness T₁. The patterning process may result in the exposure of sidewall surfaces 227 of the resist layer 220 within the openings 225 in addition to the exposure of the top surface 226 of the resist layer 220.

In an embodiment, the openings 225 may be trenches that extend into and out of the plane of FIG. 2B. The trench openings 225 may define a pattern that includes lines and spaces. Other openings 225 may include holes that pass through the resist layer 220. Patterns that include holes may be used for the formation of vias in underlying layers. While line/space patterns and hole patterns are described herein, it is to be appreciated that any suitable pattern may be formed in the resist layer 220.

Referring now to FIG. 2C, a cross-sectional illustration of the portion of the device 200 after a treatment is applied to the patterned resist layer 220 is shown, in accordance with an embodiment. In an embodiment, the treatment may result in the incorporation of sulfur into the top surface 226 and the sidewall surfaces 227 of the resist layer 220. In the case where the resist layer 220 comprises an underlayer, portions of the underlayer may also be treated by incorporating sulfur into exposed sidewalls of the underlayer. In some instances, the treatment may be generally referred to as a sulfurization process. The treatment may result in a conversion of the chemical composition of the surfaces 226 and 227 into sulfur-rich regions 224, and a bulk of the resist layer 220 may remain with the original composition. In an embodiment, the treatment may include several different types of sulfurization processes, which will be described in greater detail herein. One sulfurization process may include a plasma treatment with a sulfur comprising plasma. In order to prevent damage to the geometry of the openings and/or the thickness of the resist layer 220, the plasma-based sulfurization may be implemented without a bias. In other embodiments, non-plasma sulfurization processes may be used. In one such embodiment, a three-operation process (e.g., ultraviolet (UV) exposure, neutralization, and sulfur infusion) may be used. In another such embodiment, a two-operation process (e.g., UV exposure and sulfur infusion) may be used.

Referring now to FIG. 20, a cross-sectional illustration of a portion of the device 200 after the pattern of the openings 225 is transferred into at least a portion of the patterning stack 235 is shown, in accordance with an embodiment. In an embodiment, an etching process may be used to etch through the layer 231 and the layer 232. After the opening 225 is formed through the layer 232 (which may be a hardmask layer), the resist layer 220 may be removed with any suitable process. Thereafter, further transfer of the pattern into the underlayer may be implemented through the use of the layer 232 as the mask.

As shown, the etching process used to transfer the pattern of the openings 225 into the patterning stack 235 may be implemented without significant reduction in a thickness of the resist layer 220. For example, after etching through the hardmask layer 232, the resist layer 220 may have a second thickness T₂. In an embodiment, the second thickness T₂ may be substantially equal to the first thickness T₁. In other embodiments, the second thickness T₂ may be at least 50% of the first thickness T₁, at least 75% of the first thickness T₁, at least 90% of the first thickness T₁, or at least 95% of the first thickness T₁.

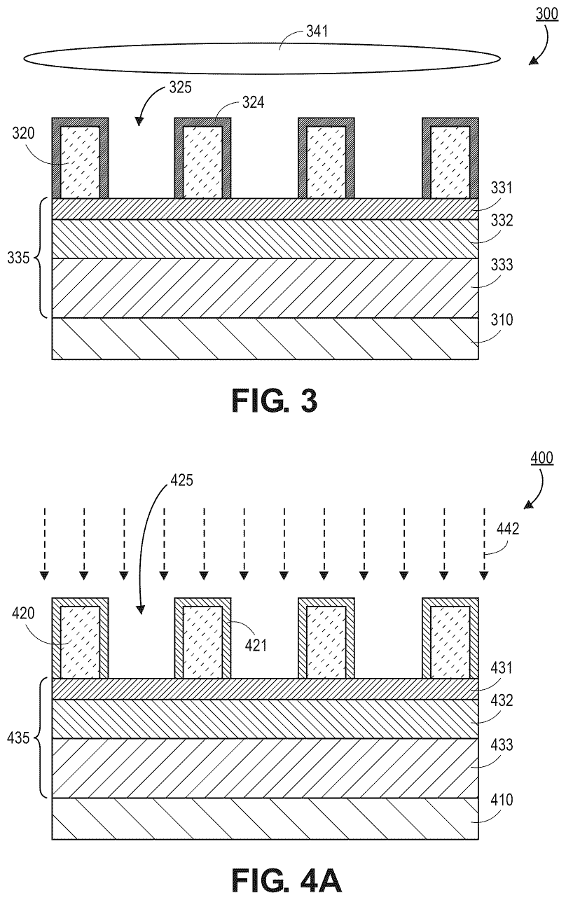

Referring now to FIG. 3, a cross-sectional illustration of a portion of a device 300 as it is being sulfurized with a plasma-based process is shown, in accordance with an embodiment. In an embodiment, the device 300 may be similar to the device 200 described with respect to FIG. 2C. For example, the device 300 may comprise a substrate 310 with an overlying patterning stack 335 (e.g., with layers 331-333). A patterned resist layer 320 may be provided over the patterning stack 335. The resist layer 320 may have openings 325 formed through a thickness of the resist layer 320. In an embodiment, the resist layer 320 may comprise a positive tone CAR material.

In an embodiment, the sulfurization process may be a plasma-based sulfurization process with a plasma 341 that comprises sulfur. For example, a source gas comprising one or more of SF₆, CS₂, COS, SO₂ may be flown into a chamber in order to form the plasma 341. In an embodiment, the sulfur ions may be incorporated into surfaces (e.g., top surface and sidewall surfaces) of the resist layer 220 to form sulfur-rich regions 324.

In an embodiment, the plasma 341 may be formed without a bias applied. As such, the ions are not accelerated towards the device 200. This prevents the plasma from altering the geometry of the openings 325 and/or reducing a thickness of the resist layer 320. In an embodiment, the plasma-based sulfurization treatment may be applied for any suitable duration of time. For example, the duration of the treatment may be up to approximately 30 seconds, up to approximately 1 minute, up to approximately 2 minutes, up to approximately 10 minutes, or up to approximately 30 minutes. Though, longer durations may also be used in other embodiments.

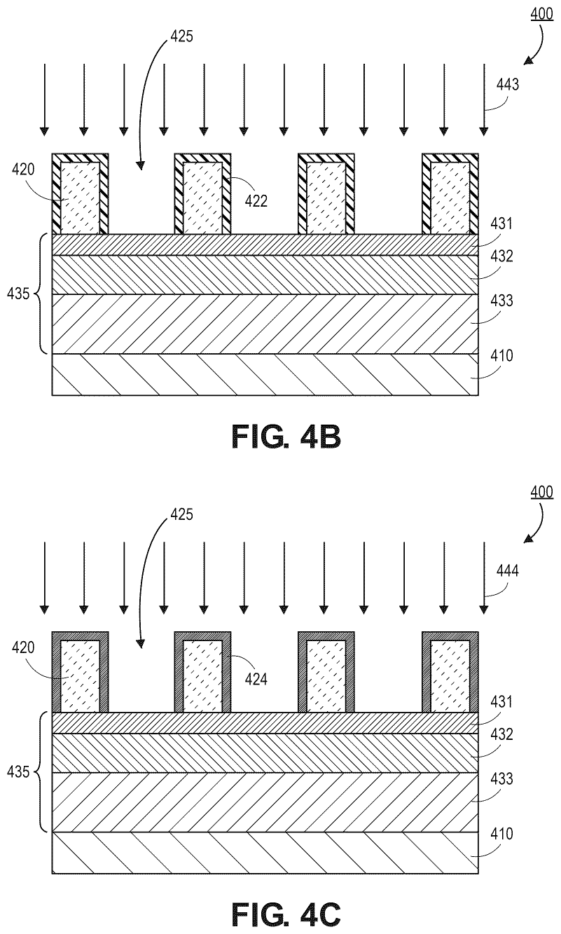

Referring now to FIGS. 4A-4C, a series of cross-sectional illustrations depicting a process for sulfurizing a resist layer 420 of a device 400 with a plasma-free process is shown, in accordance with an embodiment. In an embodiment, the device 400 may be similar to the device 200 described with respect to FIG. 2B. For example, the device 400 may comprise a substrate 410 with an overlying patterning stack 435 (e.g., with layers 431-433). A patterned resist layer 420 may be provided over the patterning stack 435. The resist layer 420 may have openings 425 formed through a thickness of the resist layer 420. In an embodiment, the resist layer 420 may comprise a positive tone CAR material.

As shown in FIG. 4A, the sulfurization treatment may comprise a first operation 442. In an embodiment, the first operation 442 may include a blanket UV exposure of the resist layer 420. In an embodiment, the blanket UV exposure may initiate the deprotection reaction within the resist layer 420. This may result in the conversion of ester resin of the resist layer 420 into deprotected carboxylic acids in the treated region 421.

Referring now to FIG. 4B, a cross-sectional illustration of the device 400 after a second operation 443 of the sulfurization process is implemented is shown, in accordance with an embodiment. In an embodiment, the second operation 443 may include exposing the resist layer 420 to a neutralization chemistry that neutralizes the carboxylic acids in the treated region 421 to form a neutralized region 422. Neutralizing the carboxylic acids may result in the formation of carboxylate salts within the neutralized region 422. In an embodiment, the neutralization chemistry may comprise an NF₃ gas or the like.

Referring now to FIG. 4C, a cross-sectional illustration of the device 400 after a third operation 444 of the sulfurization process is implemented is shown, in accordance with an embodiment. In an embodiment, the third operation 444 may include introducing sulfur into the neutralized region 422. For example, an etching chemistry that comprises sulfur (e.g., a SO₂ gas) may be applied to the resist layer 420. The gas may result in the uptake of sulfur into the resist layer 420 in order to form sulfur rich regions 424. In some embodiments, the device 400 may be held at an elevated temperature during the third operation 444. For example, the device 400 may be held at approximately 90° C. or higher, or approximately 120° C. or higher.

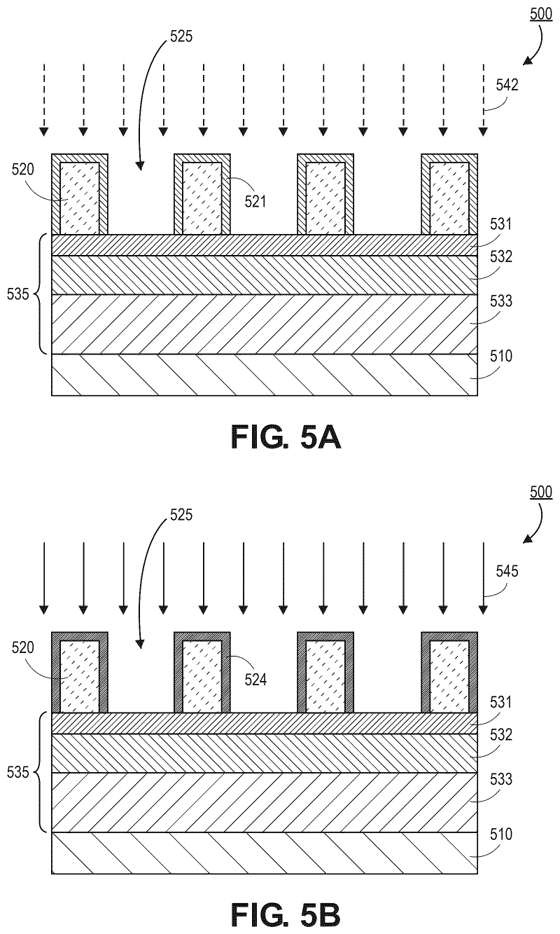

Referring now to FIGS. 5A-5B, a series of cross-sectional illustrations depicting a process for sulfurizing a resist layer 520 of a device 500 with a plasma-free process is shown, in accordance with an embodiment. In an embodiment, the device 500 may be similar to the device 200 described with respect to FIG. 2B. For example, the device 500 may comprise a substrate 510 with an overlying patterning stack 535 (e.g., with layers 531-533). A patterned resist layer 520 may be provided over the patterning stack 535. The resist layer 520 may have openings 525 formed through a thickness of the resist layer 520. In an embodiment, the resist layer 520 may comprise a positive tone CAR material.

As shown in FIG. 5A, the sulfurization treatment may comprise a first operation 542. In an embodiment, the first operation 542 may include a blanket UV exposure of the resist layer 520. In an embodiment, the blanket UV exposure may initiate the deprotection reaction within the resist layer 520. This may result in the conversion of ester resin of the resist layer 520 into deprotected carboxylic acids in the treated region 521.

Referring now to FIG. 5B, a cross-sectional illustration of the device 500 after a second operation 545 of the sulfurization process is implemented is shown, in accordance with an embodiment. In an embodiment, the second operation 545 may include introducing sulfur into the treated region 521. For example, a sulfur-based chemistry (e.g., an H₂S gas) may be applied to the resist layer 520. The gas may result in the formation thioester bonds and incorporate sulfur into the treated regions 521 to form sulfur rich regions 524. In some embodiments, the device 500 may be held at an elevated temperature during the second operation 545. For example, the device 500 may be held at approximately 90° C. or higher, or approximately 120° C. or higher.

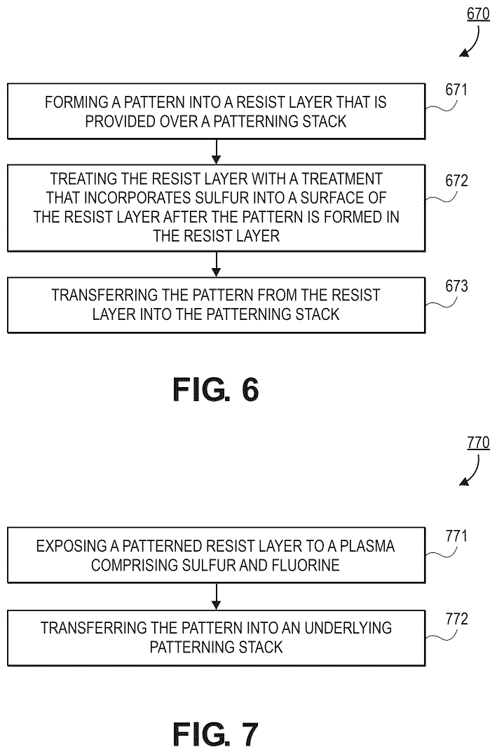

Referring now to FIG. 6, a flow diagram depicting a process 670 for patterning a device with a resist layer that has a sulfurized surface is shown, in accordance with an embodiment. In an embodiment, the process 670 may be similar to the process described with respect to FIGS. 2A-2D. In an embodiment, the process 670 may begin with operation 671, which comprises forming a pattern into a resist layer that is provided over a patterning stack. In an embodiment, the resist layer may comprise a positive tone CAR for EUV lithography or any of the other resist materials described herein. In an embodiment, the patterning stack may be similar to any of the patterning stacks described herein. In an embodiment, the pattern may comprise openings that pass through a thickness of the resist layer. The openings may include trenches, holes, or the like.

In an embodiment, the process 670 may continue with operation 672, which comprises treating the resist layer with a treatment that incorporates sulfur into a surface of the resist layer after the pattern is formed in the resist layer. In an embodiment, the treatment may be similar to any of the sulfurization treatments described in greater detail herein. For example, the treatment may be similar to treatments that will be described in greater detail with respect to FIGS. 7-9.

In an embodiment, the process 670 may continue with operation 673, which comprises transferring the pattern from the resist layer into the patterning stack. In an embodiment, the sulfurized surface of the resist layer improves the resistance of the resist layer to the etching chemistry used to etch one or more layers of the patterning stack. As such, the resist layer may have a smaller thickness when deposited, and/or the resolution of the openings may be improved compared to existing EUV resist materials. For example, the resist layer may have a thickness after pattern transfer into the patterning stack that is at least 80% of an original thickness of the resist layer.

Referring now to FIG. 7, a flow diagram of a process 770 for treating a patterned resist layer is shown, in accordance with an embodiment. In an embodiment, the process 770 may comprise a plasma-based sulfurization process. In an embodiment, the process 770 may begin with operation 771, which comprises exposing a patterned resist layer to a plasma comprising sulfur and fluorine. In an embodiment, the source gas for the plasma may comprise one or more of SF₆, CS₂, COS, SO₂. The duration of the plasma exposure may be up to 1 minute, up to 2 minutes, up to 10 minutes, or any other longer duration. In an embodiment, the plasma treatment may be implemented without a bias applied. In an embodiment, the process 770 may then continue with operation 772, which comprises transferring the pattern into an underlying patterning stack.

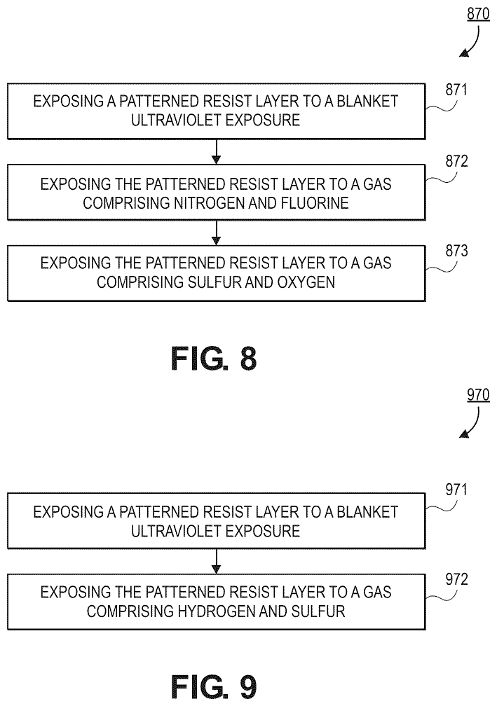

Referring now to FIG. 8, a flow diagram of a process 870 for treating a patterned resist layer is shown, in accordance with an embodiment. In an embodiment, the process 870 may be a plasma-free sulfurization treatment. In an embodiment, the process 870 may begin with operation 871, which comprises exposing a patterned resist layer to a blanket ultraviolet exposure. The blanket UV exposure may initiate a deprotection reaction at surfaces of the resist layer in order to convert ester resin into deprotected carboxylic acids.

In an embodiment, the process 870 may continue with operation 872, which comprises exposing the patterned resist layer to a gas comprising nitrogen and fluorine. For example, the gas may comprise NFs. In an embodiment, the gas may neutralize the acidic groups present at the surface of the resist layer. The neutralized surface may comprise carboxylate salts. While NF₃ is described as one neutralizing chemistry, any other neutralizing chemistry may be used in accordance with different embodiments.

In an embodiment, the process 870 may continue with operation 873, which comprises exposing the patterned resist layer to a gas that comprises sulfur and oxygen. In an embodiment, the gas may result in a reaction that drives the uptake of sulfur into the surfaces of the resist layer. In some embodiments, one or more operations of process 870 may be implemented at an elevated temperature. For example, the temperature may be held at approximately 90° C. or high or approximately 125° C. or higher.

Referring now to FIG. 9, a flow diagram of a process 970 for treating a patterned resist layer is shown, in accordance with an embodiment. In an embodiment, the process 970 may be a plasma-free sulfurization treatment. In an embodiment, the process 970 may begin with operation 971, which comprises exposing a patterned resist layer to a blanket ultraviolet exposure. The blanket UV exposure may initiate a deprotection reaction at surfaces of the resist layer in order to convert ester resin into deprotected carboxylic acids.

In an embodiment, the process 970 may continue with operation 972, which comprises exposing the patterned resist layer to a gas comprising hydrogen and sulfur. The gas may result in the formation thioester bonds and incorporate sulfur into surfaces of the resist layer. In some embodiments, one or more operations of the process 970 may be implemented at elevated temperature. For example, the temperature may be held at approximately 90° C. or higher, or approximately 120° C. or higher.

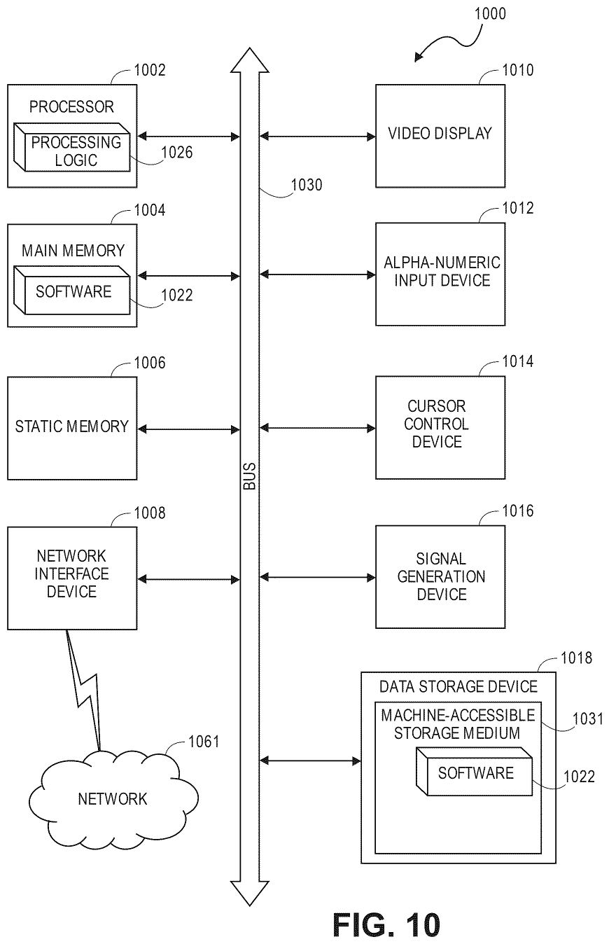

Referring now to FIG. 10, a block diagram of an exemplary computer system 1000 of a processing tool is illustrated in accordance with an embodiment. In an embodiment, computer system 1000 is coupled to and controls processing in the processing tool. Computer system 1000 may be connected (e.g., networked) to other machines in a Local Area Network (LAN), an intranet, an extranet, or the Internet. Computer system 1000 may operate in the capacity of a server or a client machine in a client-server network environment, or as a peer machine in a peer-to-peer (or distributed) network environment. Computer system 1000 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 1000, the term “machine” shall also be taken to include any collection of machines (e.g., computers) that individually or jointly execute a set (or multiple sets) of instructions to perform any one or more of the methodologies described herein.

Computer system 1000 may include a computer program product, or software 1022, having a non-transitory machine-readable medium having stored thereon instructions, which may be used to program computer system 1000 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 1000 includes a system processor 1002, a main memory 1004 (e.g., read-only memory (ROM), flash memory, dynamic random access memory (DRAM) such as synchronous DRAM (SDRAM) or Rambus DRAM (RDRAM), etc.), a static memory 1006 (e.g., flash memory, static random access memory (SRAM), etc.), and a secondary memory 1018 (e.g., a data storage device), which communicate with each other via a bus 1030.

System processor 1002 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 1002 may also be one or more special-purpose processing devices such as an application specific integrated circuit (ASIC), a field programmable gate array (FPGA), a digital signal system processor (DSP), network system processor, or the like. System processor 1002 is configured to execute the processing logic 1026 for performing the operations described herein.

The computer system 1000 may further include a system network interface device 1008 for communicating with other devices or machines. The computer system 1000 may also include a video display unit 1010 (e.g., a liquid crystal display (LCD), a light emitting diode display (LED), or a cathode ray tube (CRT)), an alphanumeric input device 1012 (e.g., a keyboard), a cursor control device 1014 (e.g., a mouse), and a signal generation device 1016 (e.g., a speaker).

The secondary memory 1018 may include a machine-accessible storage medium 1031 (or more specifically a computer-readable storage medium) on which is stored one or more sets of instructions (e.g., software 1022) embodying any one or more of the methodologies or functions described herein. The software 1022 may also reside, completely or at least partially, within the main memory 1004 and/or within the system processor 1002 during execution thereof by the computer system 1000, the main memory 1004 and the system processor 1002 also constituting machine-readable storage media. The software 1022 may further be transmitted or received over a network 1061 via the system network interface device 1008. In an embodiment, the network interface device 1008 may operate using RF coupling, optical coupling, acoustic coupling, or inductive coupling.

While the machine-accessible storage medium 1031 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A method for transferring a pattern in a resist layer into a patterning stack under the resist layer, wherein the method comprises:
treating the resist layer with a treatment that incorporates sulfur into a surface of the resist layer after the pattern is formed in the resist layer; and
transferring the pattern in the resist layer into the patterning stack.

2. The method of claim 1, wherein the treatment comprises a plasma treatment with a source gas that comprises one or more of SF₆, CS₂, COS, or SO₂.

3. The method of claim 2, wherein the plasma treatment is a bias-free plasma treatment.

4. The method of claim 1, wherein the treatment comprises:
exposing the resist layer to a blanket ultraviolet (UV) exposure after the pattern is formed;
exposing the resist layer to a first chemistry that comprises NF₃; and
exposing the resist layer to a second chemistry that comprises SO₂.

5. The method of claim 4, wherein the first chemistry and the second chemistry are applied without a plasma.

6. The method of claim 1, wherein the treatment comprises:
exposing the resist layer to a blanket ultraviolet (UV) exposure after the pattern is formed; and
exposing the resist layer to a gas comprising H₂S.

7. The method of claim 1, wherein the resist layer is a positive tone chemically amplified resist.

8. The method of claim 1, wherein the resist layer further comprises an underlayer, and wherein the treatment incorporates sulfur into the underlayer.

9. The method of claim 1, wherein the treatment comprises flowing a gas comprising sulfur over the resist layer without striking a plasma.

10. The method of claim 1, wherein a thickness of the resist layer after transferring the pattern is at least 80% of an original thickness of the resist layer.

11. A method for transferring a pattern formed into a resist layer that comprises a positive tone chemically amplified resist (CAR) into a patterning stack below the resist layer, wherein the method comprises:
treating the resist layer with a treatment that incorporates sulfur into a surface of the resist layer after the pattern is formed in the resist layer; and
wherein the surface with integrated sulfur has a higher etch resistivity than regions of the resist layer without the sulfur.

12. The method of claim 11, wherein the treatment comprises a plasma sulfurization process with a gas comprising one or more of SF₆, CS₂, COS, or SO₂.

13. The method of claim 12, wherein no plasma bias applied during the plasma sulfurization process.

14. The method of claim 11, wherein the treatment comprises:
generating acids on a surface of the resist layer after the patterning;
neutralizing the acids to generate carboxylate salts on the surface of the resist layer; and
exposing the surface to a gas comprising sulfur and oxygen.

15. The method of claim 14, wherein acids on the surface of the resist layer are generated by a blanket ultraviolet exposure.

16. The method of claim 14, wherein the resist layer is held at a temperature of 90° C. or higher for one or more operations of the treatment.

17. The method of claim 11, wherein the treatment comprises:
generating acids on a surface of the resist layer after the patterning; and
exposing the surface to a gas that comprises sulfur and hydrogen.

18. A method comprising:
treating a patterned resist layer with a treatment, wherein the resist layer is provided over a patterning stack, and wherein the treatment incorporates sulfur into a top surface of the resist layer and a sidewall surface of the resist layer; and
transferring a pattern of the patterned resist layer into the patterning stack with an etching process.

19. The method of claim 18, wherein the treatment comprises a plasma treatment with no bias.

20. The method of claim 18, wherein the treatment comprises an ultraviolet exposure of the resist layer and an exposure to a gas comprising sulfur.
